(19) United States
(12) Patent Application Publication
(10) Pub. No.: US 2014/0352620 A1
(43) Pub. Date: Dec. 4, 2014

(54) GUIDING ASSEMBLY AND COATING DEVICE USING SAME

(71) Applicant: HON HAI PRECISION INDUSTRY CO., LTD., New Taipei (TW)

(72) Inventor: SHAO-KAI PEI, New Taipei (TW)

(73) Assignee: HON HAI PRECISION INDUSTRY CO., LTD., New Taipei (TW)

(21) Appl. No.: 14/259,329

(22) Filed: Apr. 23, 2014

(30) Foreign Application Priority Data
May 28, 2013 (TW) 102118863

(51) Int. Cl. C23C 16/455; F15C 4/00; F15C 3/00

(52) U.S. Cl. CPC C23C 16/45502; F15C 3/005; F15C 4/00
USPC 118/728; 137/560

(57) ABSTRACT

A guiding assembly is used in a coating device. The coating device includes a target and an umbrella stand. The guiding assembly is located between the target and the umbrella stand, and includes a motor, a transmission unit driven by the motor, and a plurality of guiding boards driven by the transmission unit. The guiding boards are rotatable to control a direction of motion of particles stimulated from the target.

### FIELD

The present disclosure relates to a coating device and a guiding assembly used in the coating device.

### BACKGROUND

A film is usually coated on a surface of a consumer electronic device to improve the appearance of the consumer electronic device. A vacuum evaporating method is usually used to coat the film. When coating, particles stimulated from a target are deposited on the consumer electronic device to form the film. Yet, the particles usually move along some particular direction, which makes the film uneven.

Therefore, it is desirable to provide a guiding assembly and a coating device that can overcome the shortcomings mentioned above.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a schematic view of a coating device according to an exemplary embodiment of the present disclosure.

FIG. 2 is a schematic, isometric view of a guiding assembly of the coating device of FIG. 1.

FIG. 3 is an exploded view of the guiding assembly of FIG. 2.

FIG. 4 is similar to FIG. 3, but viewed from another angle.

### DETAILED DESCRIPTION

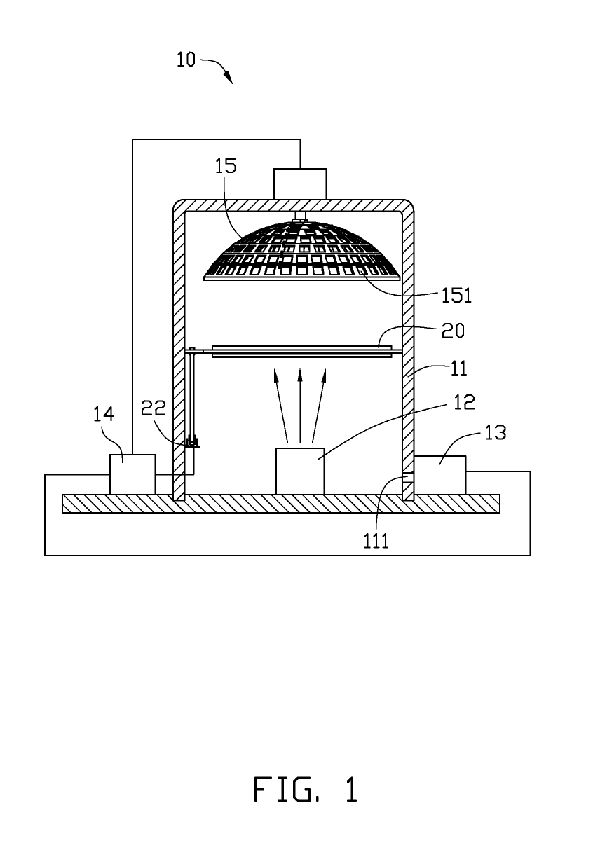

FIG. 1 shows a coating device 10 according to an exemplary embodiment of the present disclosure. The coating device 10 includes a chamber 11, a target 12, a pump 13, a controller 14, an umbrella stand 15 and a guiding assembly 20.

The target 12 is set at a bottom of the chamber 11. The chamber 11 defines a gas hole 111. The pump 14 is mounted outside the chamber 11 and is communicating with the gas hole 111. The pump 14 can create a vacuum in the chamber through the gas hole 111. The controller 14 is mounted outside the chamber 11 and is electrically connected with the pump 14 and the umbrella stand 15. The umbrella stand 15 is fixed at a top of the chamber 11 opposite to the target 12. The umbrella stand 15 is curve-shaped, and defines a plurality of supporting holes 151. The umbrella stand 15 is rotatable around a center axis. When coating, workpieces are received in the supporting holes 151, and surfaces of the workpieces to be coated face the target 12.

The guiding assembly 20 is mounted on an inner wall of the chamber 11 and is positioned between the target 12 and the umbrella stand 15, and the guiding assembly 20 is used to guide a direction of motion of particles stimulated from the target 12.

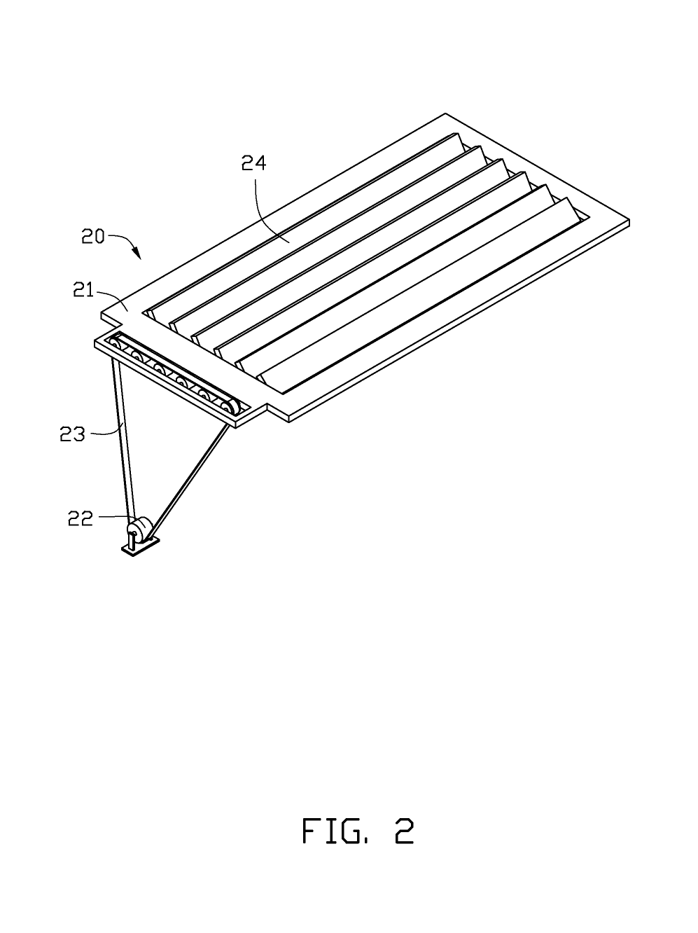

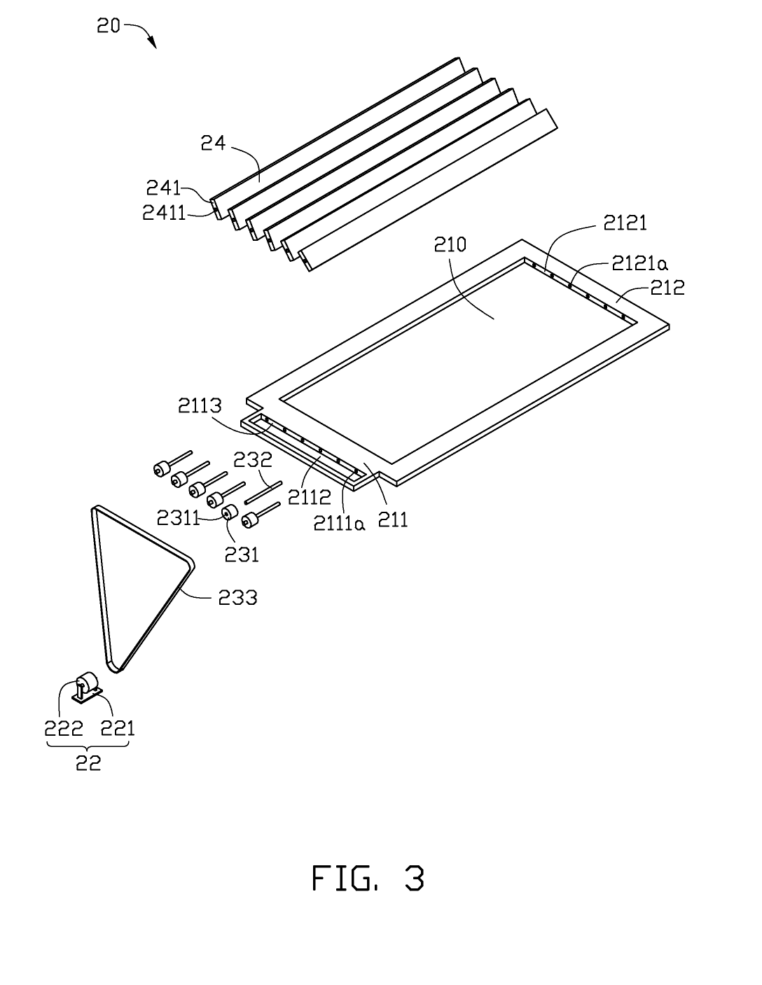

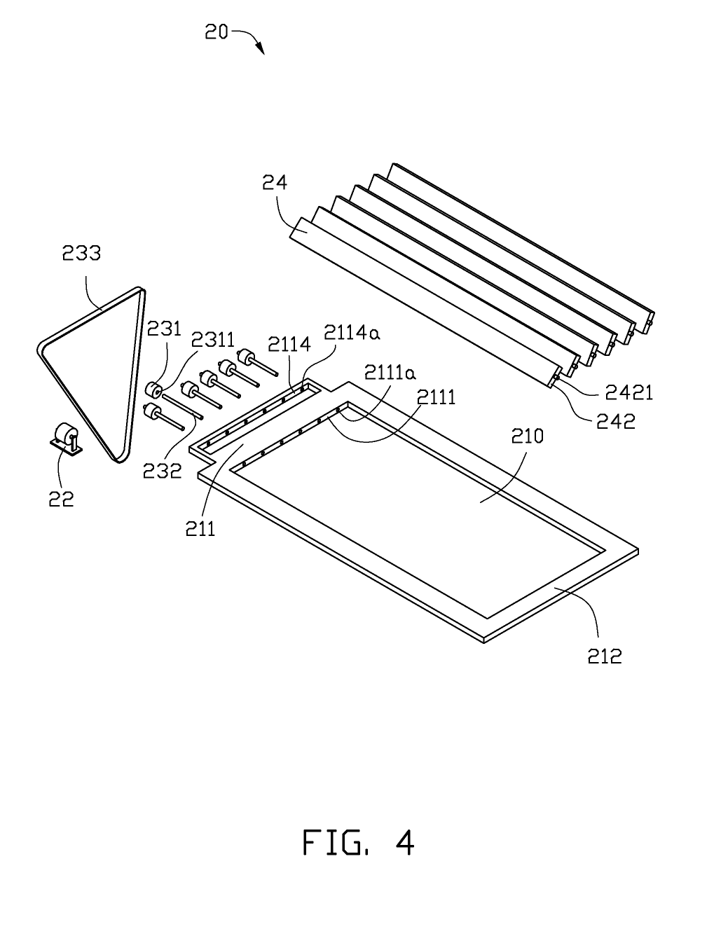

FIGS. 2, 3 and 4 show the guiding assembly 20. The guiding assembly 20 includes a fixing frame 21, a motor 22, a transmission unit 23, and a plurality of guiding boards 24.

The fixing frame 21 is substantially rectangular, and defines a rectangular opening 210. The fixing frame 21 includes a first rim 211 and a second rim 212 parallel to and opposite to each other. The first rim 211 includes a first surface 2111 facing the second rim 212. The second rim 212 includes a second surface 2121 facing the first rim 211. The first rim 211 defines a rectangular receiving hole 2112, and includes a third surface 2113 and a fourth surface 2114 parallel to the first surface 2111 and adjacent to the receiving hole 2112. The fourth surface 2114 is away from the first surface 2111 relative to the third surface 2113. The first surface 2111 defines a number of through holes 2111a extending through the first and third surfaces 2111, 2113. The second surface 2121 defines a number of first blind holes 2121a. The fourth surface 2114 defines a number of second blind holes 2114a. The first blind holes 2121a and the second blind holes 2114a respectively correspond to the through holes 2111 a.

The motor 22 is electrically connected to the controller 14. The motor 22 includes a base 221 and a driving shaft 222 mounted on the base 221. The base 221 is fixed to the inner wall of the chamber 11. The transmission unit 23 includes a number of wheels 231, a number of connecting rods 232 and a transmission belt 233. Each wheel 231 defines a shaft hole 2311 tightly engaged with one of the connecting rods 232. One end of the connecting rod 232 is received in the second blind hole 2114a, the other end of the connecting rod 232 extends through the through hole 2111 a into the opening 210. The transmission belt 233 is sheathed on the driving shaft 222 and the wheels 231. The driving shaft 222 drives the transmission belt 233 and the wheels 231 to rotate in turn.

The guiding boards 24 are strip-shaped plates, and are received in the opening 210 between the first and second surfaces 2111, 2121. Each guiding board 24 includes a first end 241 and a second end 242 opposite to the first end 241. The first end 241 defines a third blind hole 2411. The second end 242 includes a protrusion 2421. The third blind hole 2411 is tightly engaged with the connecting rod 232. The protrusion 2421 is received in the first blind hole 2121a. The protrusion 2421 is made of soft material, such as plastic, so that the guiding board 24 can be put into the opening 210.

During use, the controller 14 controls to pump 13 to create a vacuum in the chamber 11, particles are stimulated from the target 12. The controller 14 controls the umbrella stand 15 and the driving shaft 222 of the motor 22 to rotate. The driving shaft 222 drives the transmission belt 233, the wheels 231, the connecting rods 232, and the guiding boards 24 to rotate in turn. The guiding boards 24 changes the direction of motion of the particles during rotation, thus making an even film coated on the workpieces, and improving the coating quality.

It will be understood that the above particular embodiments are shown and described by way of illustration only. The principles and the features of the present disclosure may be employed in various and numerous embodiments thereof without departing from the scope of the disclosure. The above-described embodiments illustrate the scope of the disclosure but do not restrict the scope of the disclosure.

What is claimed is:

1. A guiding assembly used in a coating device, the coating device including a target and an umbrella stand, the guiding assembly being located between the target and the umbrella stand during use, the guiding assembly comprising:
a motor;
a transmission unit driven by the motor; and
a plurality of guiding boards driven by the transmission unit, the guiding boards being rotatable to control a direction of motion of particles stimulated from the target.

2. The guiding assembly of claim 1, further comprising a fixing frame, the fixing frame comprising a first rim and a second rim in parallel and opposite to the first rim, the first rim comprising a first surface facing the second rim, the second rim comprising a second surface facing the first rim, the guiding boards rotatably mounted to the fixing frame between the first surface and the second surface.

3. The guiding assembly of claim 2, wherein the first rim defines a receiving hole for receiving the transmission unit, each guiding board comprises a first end and a second end opposite to the first end, the first end is fixed to the transmission unit, the second end is rotatably mounted at the second surface.

4. The guiding assembly of claim 3, wherein the second surface defines a plurality of first blind holes, each second end comprises a protrusion rotatably engaged in one corresponding first blind hole.

5. The guiding assembly of claim 3, wherein the first rim further comprises a third surface adjacent to the receiving hole, and a fourth surface adjacent to the receiving hole and opposite to the third surface, and defines a plurality of through holes extending through the first surface and the third surface, the fourth surface defines a plurality of second blind holes, each first end of the guiding board defines a third blind hole, the transmission unit comprises a plurality of wheels sleeved over a plurality of connecting rods, one end of each connecting rod is received in one of the second blind holes, and the other end of the connecting rod extends through the through hole and is received in the third blind hole.

6. The guiding assembly of claim 5, wherein the motor comprises a base and a driving shaft mounted on the base, and the transmission unit further comprises a transmission belt sheathed on the driving shaft and the wheels.

7. A coating device comprising:
a chamber;
a target mounted at a bottom of the chamber;
an umbrella stand mounted at a top of the chamber opposite to the target; and
a guiding assembly located between the target and the umbrella stand, the guiding assembly comprising:
a motor;
a transmission unit driven by the motor; and
a plurality of guiding boards driven by the transmission unit, the guiding boards being rotatable to control a direction of motion of particles stimulated from the target.

8. The coating device of claim 7, further comprising a pump and a controller, the pump configured to create a vacuum in the chamber, the controller electrically connected to the pump, the umbrella stand, and the guiding assembly.

9. The coating device of claim 7, wherein the guiding assembly further comprises a fixing frame fixed to an inner wall of the chamber, the fixing frame comprises a first rim and a second rim in parallel and opposite to the first rim, the first rim comprises a first surface facing the second rim, the second rim comprises a second surface facing the first rim, the guiding boards are rotatably mounted to the fixing frame between the first surface and the second surface.

10. The coating device of claim 9, wherein the first rim defines a receiving hole fir receiving the transmission unit, each guiding board comprises a first end and a second end opposite to the first end, the first end is fixed to the transmission unit, and the second end is rotatably mounted at the second surface.

11. The coating device of claim 10, wherein the second surface defines a plurality of first blind holes, and each second end comprises a protrusion rotatably engaged in one corresponding first blind hole.

12. The coating device of claim 10, wherein the first rim further comprises a third surface adjacent to the receiving hole, and a fourth surface adjacent to the receiving hole and opposite to the third surface, and defines a plurality of through holes extending through the first surface and the third surface, the fourth surface defines a plurality of second blind holes, each first end of the guiding board defines a third blind hole, the transmission unit comprises a plurality of wheels sleeved over a plurality of connecting rods, one end of each connecting rod is received in one of the second blind holes, and the other end of the connecting rod extends through the through hole and is received in the third blind hole.

13. The coating device of claim 12, wherein the motor comprises a base and a driving shaft mounted on the base, the transmission unit further comprises a transmission belt sheathed on the driving shaft and the wheels.
